(19) United States
(12) Patent Application Publication
(10) Pub. No.: US 2026/0230063 A1
(43) Pub. Date: Aug. 6, 2026

(54) OSCILLATION CIRCUIT AND SEMICONDUCTOR DEVICE

(71) Applicant: ABLIC Inc., Nagano (JP)

(72) Inventor: Tomoya Takeno, Nagano (JP)

(73) Assignee: ABLIC Inc., Nagano (JP)

(21) Appl. No.: 19/458,907

(22) Filed: Jan. 25, 2026

(30) Foreign Application Priority Data
Feb. 4, 2025 (JP) 2025-016494

(51) Int. Cl. H03K 3/03; H03K 5/01

(52) U.S. Cl. CPC H03K 3/0315; H03K 5/01

(57) ABSTRACT

An oscillation circuit includes a ring oscillator and a waveform shape circuit configured to shape a waveform of an output signal of the ring oscillator. The waveform shape circuit includes: a preamplifier circuit configured to supply a first signal and a second signal which have the same frequency as a frequency of the output signal, the first signal having an opposite phase from a phase of the output signal, the second signal having an opposite phase from the phase of the first signal; and an amplitude amplifier circuit including a first transistor, a second transistor, a third transistor including a drain connected to a drain of the first transistor and a gate connected to a drain of the second transistor, and a fourth transistor including a drain connected to the drain of the second transistor and a gate connected to the drain of the first transistor.

### CROSS REFERENCE TO RELATED APPLICATIONS

This application claims the priority benefit of Japanese Patent Application No. 2025-016494, filed on February 4, 2025. The entirety of the above-mentioned patent application is hereby incorporated by reference herein and made a part of this specification.

### BACKGROUND

### 1. Field

The present invention relates to an oscillation circuit and a semiconductor device.

### 2. Description of the Related Art

Up to now, a ring oscillator has been known as a technology for generating a predetermined oscillation frequency. The ring oscillator typically includes an odd number of inverters connected in a serial ring structure. In such a technical field, a technology for supplying a stable oscillation frequency has been disclosed (see, for example, Japanese Patent Translation Publication No. 2005-533443).

In a case of using the related-art ring oscillator described above, the oscillation amplitude and frequency are fixed. The input threshold voltage of a waveform shape circuit connected to a subsequent stage, for receiving an output signal of the related-art ring oscillator, is determined by the voltage between two power supply terminals connected to the waveform shape circuit. Meanwhile, an output waveform of the related-art ring oscillator does not oscillate with the voltages of the two power supply terminals as both ends (this oscillation state is hereinafter referred to as “full-swing”). In the related-art ring oscillator, in a case in which the voltage of the power supply terminals fluctuates and a supplied power supply voltage fluctuates, a voltage value fluctuates while the amplitude of the output signal is maintained constant. That is, the output signal of the related-art ring oscillator maintains the same amplitude, but swings within a voltage value range higher or lower than a normal state before the voltage fluctuation of the power supply terminals. In order to cause the waveform shape circuit for receiving such a non-full-swing signal to be compatible with a specification having a wide operating power supply voltage range, fine adjustment of the input threshold voltage in consideration of the above-mentioned fluctuation of the output signal is required, thereby complicating the design.

The present invention has been made in view of the above-mentioned circumstances, and an object thereof is to provide an oscillation circuit and a semiconductor device which are capable of operating over a wide operating power supply voltage range with a simple circuit configuration.

### SUMMARY

An oscillation circuit according to at least one aspect of the present invention includes: a ring oscillator; and a waveform shape circuit configured to shape a waveform of an output signal of the ring oscillator, the waveform shape circuit including: a preamplifier circuit configured to generate a first signal having the same frequency as a frequency of the output signal of the ring oscillator and having an opposite phase from a phase of the output signal of the ring oscillator; and an amplitude amplifier circuit including: a first transistor including a gate for receiving the first signal, a source connected to a first power supply terminal configured to supply a first power supply voltage, and a drain; a second transistor including a gate for receiving a second signal having the same frequency as the frequency of the first signal and having an opposite phase from the phase of the first signal, a source connected to the first power supply terminal, and a drain; a third transistor including a drain connected to the drain of the first transistor, a gate connected to the drain of the second transistor, and a source connected to a second power supply terminal configured to supply a second power supply voltage; and a fourth transistor including a drain connected to the drain of the second transistor, a gate connected to the drain of the first transistor, and a source connected to the second power supply terminal.

According to the oscillation circuit and the semiconductor device, it is possible to achieve operation over a wide operating power supply voltage range with a simple circuit configuration.

### BRIEF DESCRIPTION OF THE DRAWINGS

FIG. 1 is a block diagram for illustrating an example of an oscillation circuit and a semiconductor device according to at least one embodiment of the present invention.

FIG. 2 is a circuit diagram for illustrating an example of a configuration and connection of a current control circuit and a ring oscillator in the oscillation circuit and the semiconductor device according to the at least one embodiment.

FIG. 3 is a circuit diagram for illustrating a modification example of the configuration and connection of the current control circuit and the ring oscillator in the oscillation circuit and the semiconductor device according to the at least one embodiment.

FIG. 4 is a circuit diagram for illustrating an example of a waveform shape circuit in the oscillation circuit and the semiconductor device according to the at least one embodiment.

FIG. 5 is a circuit diagram for illustrating a modification example of the waveform shape circuit in the oscillation circuit and the semiconductor device according to the at least one embodiment.

### DESCRIPTION OF THE EMBODIMENTS

Now, an oscillation circuit and a semiconductor device according to aspects of the present invention are described by listing preferred embodiments and by referring to the accompanying drawings. In the accompanying drawings, the scale, quantity, and the like may be different from the actual scale, quantity, and the like to facilitate understanding of each configuration.

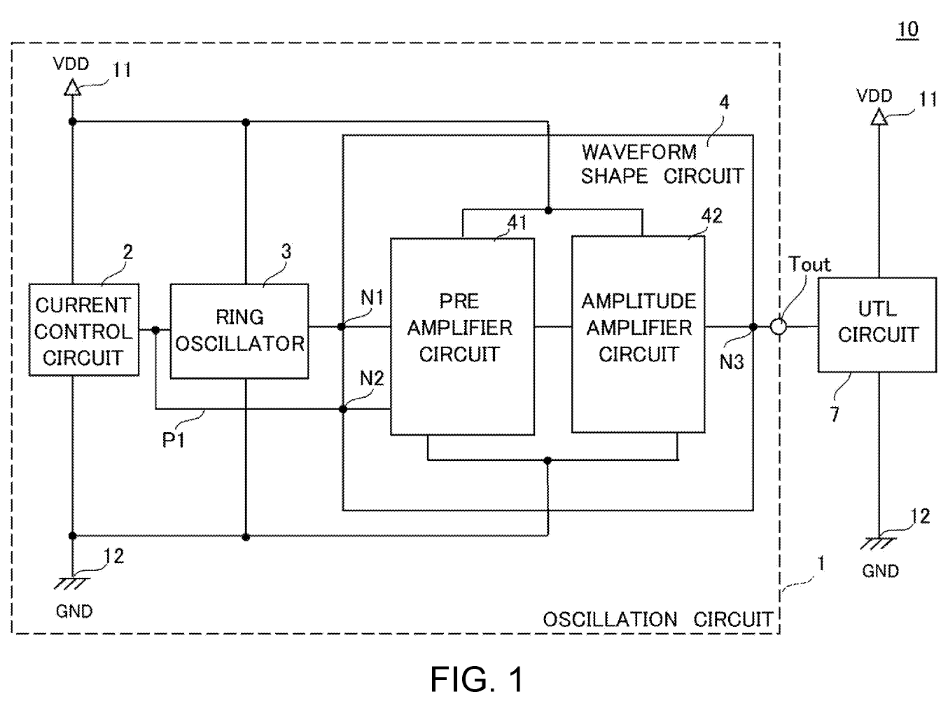

FIG. 1 is a block diagram for illustrating a semiconductor device 10 serving as an example of the semiconductor device according to at least one embodiment of the present invention. The semiconductor device 10 includes an oscillation circuit 1 and a utilization circuit (which will be described to as “UTL circuit” in FIG. 1) 7. The oscillation circuit 1 and the utilization circuit 7 are each connected to a positive power supply terminal 11 for supplying a voltage VDD serving as a first power supply voltage or a second power supply voltage, and a negative power supply terminal 12 for supplying a voltage GND (for example, 0 V) serving as the second power supply voltage or the first power supply voltage.

The oscillation circuit 1 generates a signal having a predetermined frequency. Specifically, the oscillation circuit 1 includes a ring oscillator 3. Thus, the oscillation circuit 1 generates a signal having a predetermined frequency by oscillation using the propagation delay of an inverter. The oscillation circuit 1 supplies the generated signal to the utilization circuit 7.

The utilization circuit 7 performs predetermined processing by using the signal provided by the oscillation circuit 1 as an input signal. The utilization circuit 7 is, for example, a digital circuit for performing digital signal processing, such as clock synchronization processing, by using the signal provided by the oscillation circuit 1 as a clock signal.

The oscillation circuit 1 includes, for example, a current control circuit 2, the ring oscillator 3, and a waveform shape circuit 4.

The current control circuit 2 is connected between the positive power supply terminal 11 and the negative power supply terminal 12. The current control circuit 2 has an output node connected to the ring oscillator 3 and the waveform shape circuit 4. The current control circuit 2 supplies a predetermined bias voltage to each of the ring oscillator 3 and the waveform shape circuit 4 from the output node.

The ring oscillator 3 is connected between the positive power supply terminal 11 and the negative power supply terminal 12. The ring oscillator 3 has a bias supply node that is supplied with the bias voltage, and an output node connected to the waveform shape circuit 4. The ring oscillator 3 supplies a signal (a signal having a predetermined frequency) obtained as a result of oscillation from the output node of the ring oscillator 3 to the waveform shape circuit 4.

The waveform shape circuit 4 includes a preamplifier circuit 41 and an amplitude amplifier circuit 42.

The waveform shape circuit 4 includes a node N1 and a node N2 as input nodes. The waveform shape circuit 4 also has a node N3 as an output node. An output signal from the ring oscillator 3 is supplied to the node N1. The bias voltage is applied to the node N2 by the current control circuit 2. A signal having a waveform shaped by the waveform shape circuit 4 is provided from the node N3. The node N3 is electrically the same node as an output terminal Tout of the oscillation circuit 1.

The preamplifier circuit 41 is connected between the positive power supply terminal 11 and the negative power supply terminal 12. The preamplifier circuit 41 performs processing by using, as input, an output signal from the ring oscillator 3 and a constant current provided from the current control circuit 2. The preamplifier circuit 41 generates at least a first signal having the same frequency as that of the output signal from the ring oscillator 3 and having an opposite phase from that of the output signal from the ring oscillator 3. The preamplifier circuit 41 supplies, to the amplitude amplifier circuit 42, the generated first signal and a second signal having the same frequency as that of the first signal and having an opposite phase from that of the first signal, that is, having the same frequency and the same phase as those of the output signal from the ring oscillator 3.

The amplitude amplifier circuit 42 is connected between the positive power supply terminal 11 and the negative power supply terminal 12. The amplitude amplifier circuit 42 amplifies the first signal and the second signal supplied from the preamplifier circuit 41 into signals having an amplitude that is full-swing between the positive power supply terminal 11 and the negative power supply terminal 12 and having the same frequency as those of the first signal and the second signal. The amplitude amplifier circuit 42 supplies the amplified signals to the node N3.

The signal provided from the ring oscillator 3 has a rounded waveform, to a greater or lesser extent, due to a capacitive component of an inverter included in the ring oscillator 3 (a degree of the rounding can also be said to be the magnitude of the time constant). The oscillation circuit 1 includes the waveform shape circuit 4, thereby being able to shape the waveform and to provide the signal having the shaped waveform to the utilization circuit 7. That is, the waveform shape circuit 4 can provide, from the output terminal Tout, an output signal shaped into a full-swing waveform while reducing the rounding of the waveform of the signal provided by the ring oscillator 3.

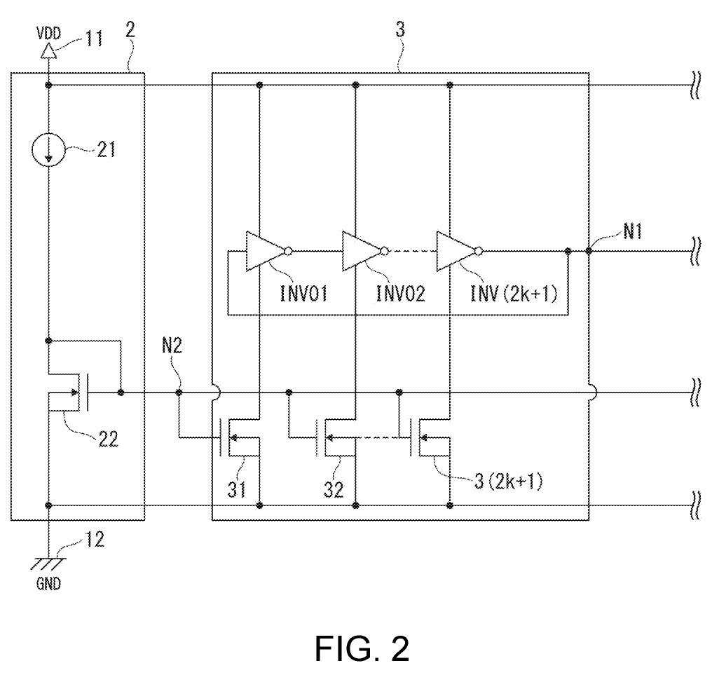

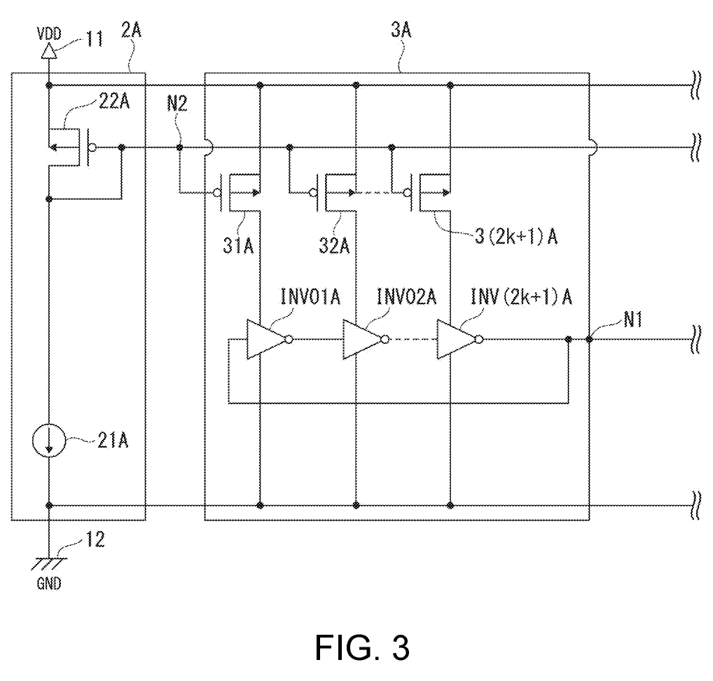

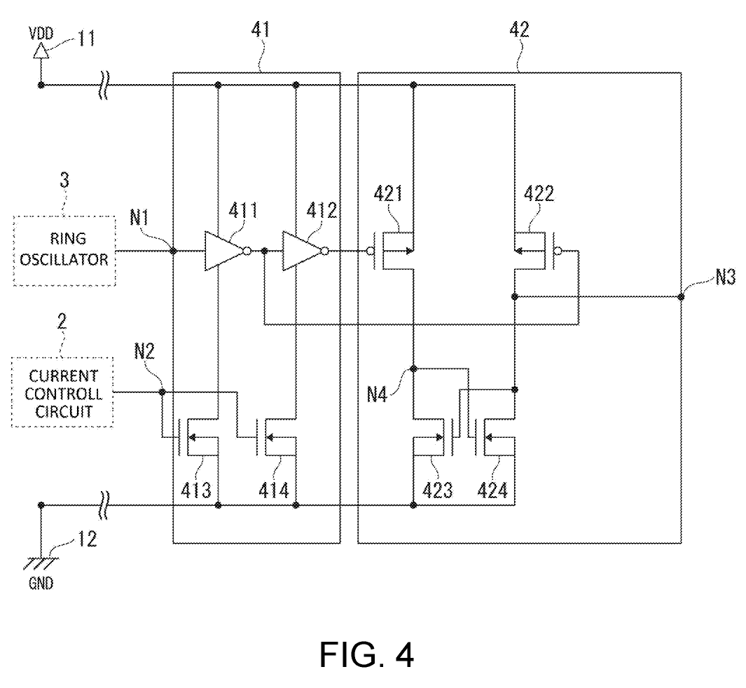

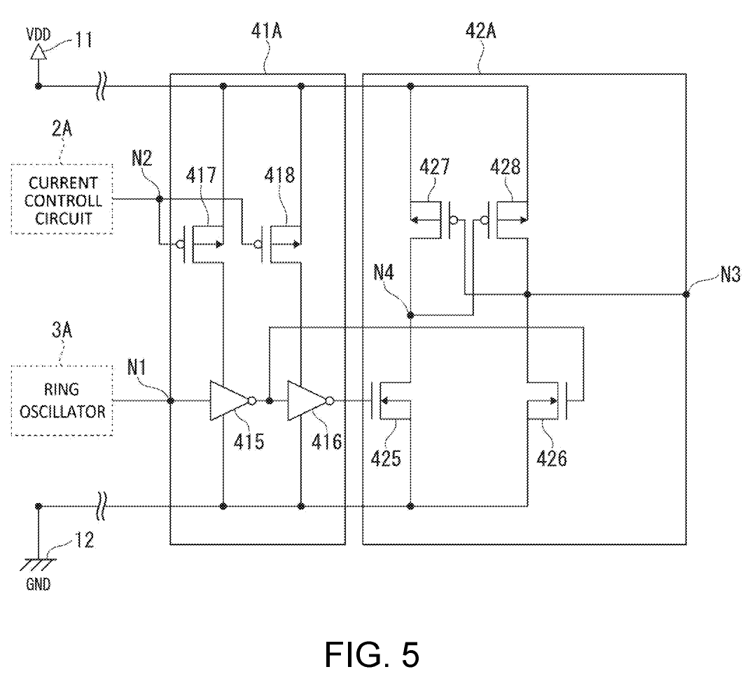

A specific configuration of the current control circuit 2 and the ring oscillator 3 can include a configuration using N-channel transistors and a configuration using P-channel transistors. Specific circuit configurations thereof are described later with reference to FIG. 2 and FIG. 3. In regard to details of each configuration included in the waveform shape circuit 4, a configuration using N-channel transistors and a configuration using P-channel transistors are conceivable. Specific circuit configurations thereof are described later with reference to FIG. 4 and FIG. 5.

FIG. 2 is a circuit diagram for illustrating an example of the configuration and connection of the current control circuit 2 and the ring oscillator 3 exemplifying the current control circuit and the ring oscillator in the oscillation circuit and the semiconductor device according to the at least one embodiment. The configuration illustrated as an example in FIG. 2 is an example of the configuration using N-channel transistors.

The current control circuit 2 includes a constant current source 21 and a transistor 22.

The constant current source 21 supplies a constant current from the positive power supply terminal 11 toward the negative power supply terminal 12. Here, out of both ends of the constant current source 21, one end of the constant current source 21 on the upstream side of the supplied electric current (the positive power supply terminal 11 side of FIG. 2) is referred to as “first end.” The other end of the constant current source 21 on the downstream side of the supplied electric current (the negative power supply terminal 12 side of FIG. 2) is referred to as “second end.”

The transistor 22 is, for example, an N-channel metal-oxide-semiconductor field-effect transistor (MOSFET). The transistor 22 has a source connected to the negative power supply terminal 12. The transistor 22 has a drain connected to the second end of the constant current source 21. The transistor 22 has a gate connected to the drain of the transistor 22. The gate and the drain of the transistor 22 serve as the output node of the current control circuit 2, and are electrically the same node as the node N2.

The ring oscillator 3 includes an inverter INV01, an inverter INV02, ..., an inverter INV(2k+1), a transistor 31, a transistor 32, ..., and a transistor 3(2k+1). The symbol “k” is a natural number equal to or greater than 1. That is, in the ring oscillator 3, an odd number of stages of inverters equal to or greater than three stages are connected in a ring shape. The transistor 31 corresponds to the inverter INV01. The transistor 32 corresponds to the inverter INV02. The transistor 3(2k+1) corresponds to the inverter INV(2k+1). Here, the correspondence between the inverter INV(2k+1) and the transistor 3(2k+1) means that the inverter INV(2k+1) and the transistor 3(2k+1) are connected in series in a path connecting the positive power supply terminal 11 and the negative power supply terminal 12. Further, a group of elements having an inverter and a transistor corresponding to the inverter that are provided on the same path is referred to as “inverter circuit.” For example, the first stage inverter circuit in the ring oscillator 3 corresponds to a circuit including the inverter INV01 and the transistor 31.

In the description referring to FIG. 2, the inverter INV01, the inverter INV02, ..., and the inverter INV(2k+1) may be simply described as an inverter, a plurality of inverters, or the like unless otherwise distinguished. Further, the transistor 31, the transistor 32, ..., and the transistor 3(2k+1) may be simply described as a transistor, a plurality of transistors, or the like unless otherwise distinguished.

Positive power supply nodes of the plurality of inverters are all connected to the positive power supply terminal 11. Negative power supply nodes of the plurality of inverters are all connected to the drains of the corresponding transistors. The plurality of inverters are connected to each other in a ring shape. Specifically, the plurality of inverters are connected in series to each other. An output node of the final stage inverter (the inverter INV(2k+1) in the illustrated example) is connected to an input node of the first stage inverter (the inverter INV01 in the illustrated example).

Sources of the plurality of transistors are all connected to the negative power supply terminal 12. Gates of the plurality of transistors are all connected to the output node of the current control circuit 2 (the gate of the transistor 22). Drains of the plurality of transistors are connected to the respective negative power supply nodes of the corresponding inverters. Each of the transistors forming the plurality of transistors and the transistor 22 form each current mirror circuit. A ratio (mirror ratio) of the drain current of each transistor to the drain current of the transistor 22 is appropriately set in accordance with the current value of the constant current source 21 and the current value for driving the corresponding inverter. For example, in a case in which the ratio of the drain current of each transistor to the drain current of the transistor 22 is 1:1, the drain current of each transistor is controlled to be equal to the drain current of the transistor 22, that is, the electric current supplied from the constant current source 21. The current value for driving the inverter is controlled by controlling the drain current of the transistor corresponding to the inverter.

FIG. 3 is a circuit diagram for illustrating a modification example of the configuration and connection of the current control circuit and the ring oscillator in the oscillation circuit and the semiconductor device according to the at least one embodiment. A current control circuit 2A is a modification example of the current control circuit 2. A ring oscillator 3A is a modification example of the ring oscillator 3. The configuration illustrated as an example in FIG. 3 is an example of the configuration using P-channel transistors.

The current control circuit 2A includes a constant current source 21A and a transistor 22A.

The constant current source 21A supplies a constant current from the positive power supply terminal 11 toward the negative power supply terminal 12. Here, out of both ends of the constant current source 21A, one end of the constant current source 21A on the upstream side (the positive power supply terminal 11 side of FIG. 3) of the supplied electric current is referred to as “first end.” The other end of the constant current source 21A on the downstream side (the negative power supply terminal 12 side of FIG. 3) of the supplied electric current is referred to as “second end.”

The transistor 22A is, for example, a P-channel MOSFET. The transistor 22A has a source connected to the positive power supply terminal 11. The transistor 22A has a drain connected to the first end of the constant current source 21A. The transistor 22A has a gate connected to the drain of the transistor 22A. The gate and the drain of the transistor 22A serve as an output node of the current control circuit 2A, and are electrically the same node as the node N2.

The ring oscillator 3A includes an inverter INV01A, an inverter INV02A, ..., an inverter INV(2k+1)A, a transistor 31A, a transistor 32A, ..., and a transistor 3(2k+1)A. The symbol “k” is a natural number equal to or greater than 1. That is, in the ring oscillator 3A, an odd number of stages of inverters are connected in a ring shape. The transistor 31A corresponds to the inverter INV01A. The transistor 32A corresponds to the inverter INV02A. The transistor 3(2k+1)A corresponds to the inverter INV(2k+1)A.

In the description referring to FIG. 3, the inverter INV01A, the inverter INV02A, ..., and the inverter INV(2k+1)A may be simply described as an inverter, a plurality of inverters, or the like unless otherwise distinguished. Further, the transistor 31A, the transistor 32A, ..., and the transistor 3(2k+1)A may be simply described as a transistor, a plurality of transistors, or the like unless otherwise distinguished.

Positive power supply nodes of the plurality of inverters are all connected to drains of the corresponding transistors. Negative power supply nodes of the plurality of inverters are all connected to the negative power supply terminal 12. The plurality of inverters are connected to each other in a ring shape. Specifically, the plurality of inverters are connected in series to each other. An output node of the final stage inverter (the inverter INV(2k+1)A in the illustrated example) is connected to the input node of the first stage inverter (the inverter INV01A in the illustrated example).

Sources of the plurality of transistors are all connected to the positive power supply terminal 11. Gates of the plurality of transistors are all connected to the output node of the current control circuit 2A (the gate of the transistor 22A). The drains of the plurality of transistors are connected to the respective positive power supply nodes of the corresponding inverters. The point that each of the transistors forming the plurality of transistors and the transistor 22A form each current mirror circuit is similar to the above-mentioned configuration using N-channel transistors. Accordingly, the drain current of each transistor is controlled to a current value proportional to the drain current of the transistor 22A, that is, the electric current supplied from the constant current source 21A. The current value for driving the inverter is controlled by controlling the drain current of the transistor corresponding to the inverter.

FIG. 4 is a circuit diagram for illustrating an example of the waveform shape circuit in the oscillation circuit and the semiconductor device according to the at least one embodiment. An example of the specific circuit configuration of the preamplifier circuit 41 and the amplitude amplifier circuit 42 is described with reference to FIG. 4.

The preamplifier circuit 41 includes at least one stage of an inverter circuit configured to be able to control the drive current of an inverter. The preamplifier circuit 41 includes a node for providing the first signal and a node for providing the second signal. The preamplifier circuit 41 includes, for example, a first stage inverter 411, a second stage inverter 412, a first stage transistor 413, and a second stage transistor 414. The first stage inverter 411 and the first stage transistor 413 connected in series to the inverter 411 in the path connecting the positive power supply terminal 11 and the negative power supply terminal 12 form a first stage inverter circuit. The second stage inverter 412 and the second stage transistor 414 connected in series to the inverter 412 in the path connecting the positive power supply terminal 11 and the negative power supply terminal 12 form a second stage inverter circuit.

A positive power supply node of the inverter 411 is connected to the positive power supply terminal 11. A negative power supply node of the inverter 411 is connected to a drain of the transistor 413. An input node of the inverter 411 is connected to the output node of the ring oscillator 3, that is, the node N1. An output node of the inverter 411 corresponds to the node for providing the first signal, and is connected to an input node of the inverter 412 and the amplitude amplifier circuit 42.

A positive power supply node of the inverter 412 is connected to the positive power supply terminal 11. A negative power supply node of the inverter 412 is connected to the drain of the transistor 414. The input node of the inverter 412 is connected to the output node of the inverter 411. An output node of the inverter 412 corresponds to the node for providing the second signal, and is connected to the amplitude amplifier circuit 42.

The transistor 413 is, for example, an N-channel MOSFET. The transistor 413 has a source connected to the negative power supply terminal 12. The transistor 413 has the drain connected to the negative power supply node of the inverter 411. The transistor 413 has a gate connected to the output node of the current control circuit 2, that is, the node N2.

The transistor 414 is, for example, an N-channel MOSFET. The transistor 414 has a source connected to the negative power supply terminal 12. The transistor 414 has a drain connected to the negative power supply node of the inverter 412. The transistor 414 has a gate connected to the output node of the current control circuit 2, that is, the node N2.

The transistor 413 and the transistor 414 serving as current control transistors in the preamplifier circuit 41, and the transistor 22 form each current mirror circuit with the above-mentioned connection relationship. A ratio of the drain current of the first stage transistor 413 to the drain current of the transistor 22 is appropriately set in accordance with the current value of the constant current source 21 and the current value for driving the first stage inverter 411. A ratio of the drain current of the second stage transistor 414 to the drain current of the transistor 22 is appropriately set in accordance with the current value of the constant current source 21 and the current value for driving the second stage inverter 412. That is, the transistors 413 and 414 are configured similarly to the transistors 31, 32, ..., and 3(2k+1) in the respective stages of the ring oscillator 3 or the transistors 31A, 32A, ..., and 3(2k+1)A in the respective stages of the ring oscillator 3A.

The electric current for driving the first stage inverter 411 is controlled by controlling the drain current of the transistor 413 in the same stage. For example, when the ratio of the drain current of the transistor 413 to the drain current of the transistor 22 is 1:1, the drain current of the transistor 413 is controlled to be equal to the drain current of the transistor 22, that is, the electric current supplied from the constant current source 21. In this manner, the drain current of the transistor 413 is controlled by the current supplied from the constant current source 21, that is, the electric current for controlling the driving of the ring oscillator 3 or 3A.

The amplitude amplifier circuit 42 includes a transistor 421, a transistor 422, a transistor 423, and a transistor 424. In the following description, the transistor 422 for receiving the first signal may be referred to as “first transistor.” The transistor 421 for receiving the second signal may be referred to as “second transistor.” The transistor 424 may be referred to as “third transistor.” The transistor 423 may be referred to as “fourth transistor.” The first transistor and the second transistor form an input transistor pair.

The transistor 421 is, for example, a P-channel MOSFET. The transistor 421 has a source connected to the positive power supply terminal 11. The transistor 421 has a drain connected to a drain of the transistor 423. The transistor 421 serving as the second transistor has a gate connected to the node for providing the second signal of the preamplifier circuit 41. Specifically, the gate is connected to the output node of the inverter 412.

The transistor 422 is, for example, a P-channel MOSFET. The transistor 422 has a source connected to the positive power supply terminal 11. The transistor 422 has a drain connected to a drain of the transistor 424. A connection point of the drain of the transistor 422 and the drain of the transistor 424 corresponds to the node N3. The transistor 422 serving as the first transistor has a gate connected to, for example, a connection point of the output node of the inverter 411 and the input node of the inverter 412 included in the preamplifier circuit 41, that is, to the node for providing the first signal.

Here, the first signal and the second signal opposite in phase to each other are supplied to the gates of the transistor 421 and the transistor 422 forming the input transistor pair. The amplitude amplifier circuit 42 performs amplitude amplification based on the supplied first signal and second signal.

The transistor 423 and the transistor 424 are, for example, N-channel MOSFETs. The pair of the transistor 423 and the transistor 424 are cross-coupled to the pair of the transistor 421 and the transistor 422.

A specific connection relationship thereof is described as follows. The transistor 423 has a source connected to the negative power supply terminal 12. The transistor 423 has a drain connected to the drain of the transistor 421 and the gate of the transistor 424. The transistor 423 has a gate connected to the drain of the transistor 424. The transistor 424 has a source connected to the negative power supply terminal 12. The transistor 424 has the drain connected to the drain of the transistor 422 and the gate of the transistor 423. The transistor 424 has a gate connected to the drain of the transistor 423 connected to the drain of the transistor 421. Here, a connection point of the gate of the transistor 424, the drain of the transistor 421, and the drain of the transistor 423 is referred to as “node N4.” The signal at the node N4 has the same amplitude and frequency as those of the signal at the node N3, and has an opposite phase relationship from that of the signal at the node N3.

FIG. 5 is a circuit diagram for illustrating a modification example of the waveform shape circuit in the oscillation circuit and the semiconductor device according to the at least one embodiment. A preamplifier circuit 41A is a modification example of the preamplifier circuit 41. An amplitude amplifier circuit 42A is a modification example of the amplitude amplifier circuit 42. An example of the specific circuit configuration of the preamplifier circuit 41A and the amplitude amplifier circuit 42A is described with reference to FIG. 5.

The preamplifier circuit 41A includes at least one stage of an inverter circuit configured to be able to control the drive current of an inverter. The preamplifier circuit 41A includes, for example, a first stage inverter 415, a second stage inverter 416, a first stage transistor 417, and a second stage transistor 418. The first stage inverter 415 and the first stage transistor 417 connected in series to the inverter 415 in the path connecting the positive power supply terminal 11 and the negative power supply terminal 12 form a first stage inverter circuit. The second stage inverter 416 and the second stage transistor 418 connected in series to the inverter 416 in the path connecting the positive power supply terminal 11 and the negative power supply terminal 12 form a second stage inverter circuit.

A positive power supply node of the inverter 415 is connected to a drain of the transistor 417. A negative power supply node of the inverter 415 is connected to the negative power supply terminal 12. An input node of the inverter 415 is connected to the output node of the ring oscillator 3, that is, the node N1. An output node of the inverter 415 corresponds to the node for providing the first signal, and is connected to an input node of the inverter 416 and the amplitude amplifier circuit 42A.

A positive power supply node of the inverter 416 is connected to a drain of the transistor 418. A negative power supply node of the inverter 416 is connected to the negative power supply terminal 12. The input node of the inverter 416 is connected to the output node of the inverter 415. An output node of the inverter 416 corresponds to the node for providing the second signal, and is connected to the amplitude amplifier circuit 42A.

The transistor 417 is, for example, a P-channel MOSFET. The transistor 417 has a source connected to the positive power supply terminal 11. The transistor 417 has the drain connected to the positive power supply node of the inverter 415. The transistor 417 has a gate connected to the output node of the current control circuit 2A, that is, the node N2.

The transistor 418 is, for example, a P-channel MOSFET. The transistor 418 has a source connected to the positive power supply terminal 11. The transistor 418 has the drain connected to the positive power supply node of the inverter 416. The transistor 418 has a gate connected to the output node of the current control circuit 2A, that is, the node N2.

The transistor 417 and the transistor 418 serving as current control transistors in the preamplifier circuit 41A, and the transistor 22A form each current mirror circuit with the above-mentioned connection relationship. A ratio of the drain current of the first stage transistor 417 to the drain current of the transistor 22A is appropriately set in accordance with the current value of the constant current source 21A and the current value for driving the first stage inverter 415. A ratio of the drain current of the second stage transistor 418 to the drain current of the transistor 22A is appropriately set in accordance with the current value of the constant current source 21A and the current value for driving the second stage inverter 416. That is, the transistors 417 and 418 are configured similarly to the transistors 31, 32, ..., and 3(2k+1) in the respective stages of the ring oscillator 3 or the transistors 31A, 32A, ..., and 3(2k+1)A in the respective stages of the ring oscillator 3A.

The electric current for driving the first stage inverter 415 is controlled by controlling the drain current of the transistor 417 in the same stage. For example, when the ratio of the drain current of the transistor 417 to the drain current of the transistor 22A is 1:1, the drain current of the transistor 417 is controlled to be equal to the drain current of the transistor 22A, that is, the electric current supplied from the constant current source 21A. In this manner, the drain current of the transistor 417 is controlled by the electric current supplied from the constant current source 21A, that is, the electric current for controlling the driving of the ring oscillator 3 or 3A.

The amplitude amplifier circuit 42A includes a transistor 425, a transistor 426, a transistor 427, and a transistor 428. The transistor 425 and the transistor 426 form an input transistor pair.

The transistor 425 serving as the second transistor is, for example, an N-channel MOSFET. The transistor 425 has a source connected to the negative power supply terminal 12. The transistor 425 has a drain connected to a drain of the transistor 427 serving as the fourth transistor. The transistor 425 has a gate connected to the node for providing the second signal of the preamplifier circuit 41A, specifically, to the output node of the inverter 416.

The transistor 426 serving as the first transistor is, for example, an N-channel MOSFET. The transistor 426 has a source connected to the negative power supply terminal 12. The transistor 426 has a drain connected to a drain of the transistor 428. A connection point of the drain of the transistor 426 and the drain of the transistor 428 serving as the third transistor corresponds to the node N3. The transistor 426 has a gate connected to, for example, a connection point of the output node of the inverter 415 and the input node of the inverter 416 included in the preamplifier circuit 41A, that is, to the node for providing the first signal.

Here, the first signal and the second signal are opposite in phase to each other, and are supplied to the gates of the transistor 425 and the transistor 426 forming the input transistor pair. The amplitude amplifier circuit 42A performs amplitude amplification based on the supplied first signal and second signal.

The transistor 427 and the transistor 428 are, for example, P-channel MOSFETs. The pair of the transistor 427 and the transistor 428 are cross-coupled to the pair of the transistor 425 and the transistor 426.

The transistor 427 has a source connected to the positive power supply terminal 11. The transistor 427 has the drain connected to the drain of the transistor 425 and a gate of the transistor 428. The transistor 427 has a gate connected to a drain of the transistor 428. The transistor 428 has a source connected to the positive power supply terminal 11. The transistor 428 has the drain connected to the drain of the transistor 426 and the gate of the transistor 427. The transistor 428 has the gate connected to the drain of the transistor 427 connected to the drain of the transistor 425. Here, a connection point of the gate of the transistor 428, the drain of the transistor 425, and the drain of the transistor 427 is referred to as “node N4.” The signal at the node N4 has the same amplitude and frequency as those of the signal at the node N3, and has an opposite phase relationship from that of the signal at the node N3.

As described above, according to the at least one embodiment, it is possible to cause the output signal of the ring oscillator 3 to be full-swing between the positive power supply terminal 11 and the negative power supply terminal 12 by inserting the amplitude amplifier circuit 42 at the output node of the ring oscillator 3. According to the at least one embodiment, it is possible to cause the output signal of the ring oscillator 3 to be full-swing, thereby enabling compatibility with a specification having a wide operating power supply voltage range. Further, in the at least one embodiment, fine adjustment of the input threshold voltage is not required, thereby no longer requiring a complicated circuit. As a result, according to the at least one embodiment, it is possible to achieve compatibility with a specification having a wide operating power supply voltage range in a simple manner.

The at least one embodiment has been used to describe modes for carrying out the present invention. However, the present invention is in no way limited to the at least one embodiment thus described above. Various modifications and substitutions can be added without departing from the gist of the present invention. That is, the above-mentioned constituent elements include elements that can be easily assumed by those skilled in the art and elements that are substantially the same. Those constituent elements may be appropriately combined.

For example, the preamplifier circuit 41 illustrated in FIG. 4 and the preamplifier circuit 41A illustrated in FIG. 5 are examples having two stages of inverter circuits, but the second stage inverter circuit may be omitted. That is, in the case of the preamplifier circuit 41 illustrated as an example in FIG. 4, the second stage inverter 412 and the second stage transistor 414 may be omitted. In the case of the preamplifier circuit 41A illustrated as an example in FIG. 5, the second stage inverter 416 and the second stage transistor 418 may be omitted. In the case of omitting the second stage inverter circuit, the node serving as a supply source of the second signal may be set to the input node of the first stage inverter 411 or inverter 415 instead of the output node of the omitted inverter 412 or inverter 416.

The amplitude amplifier circuit 42 illustrated in FIG. 4 and the amplitude amplifier circuit 42A illustrated in FIG. 5 are examples of a case in which the node N3 is the output node, that is, a case in which the node N3 corresponds to the output node of the waveform shape circuit 4. However, the node N4 may be the output node of the amplitude amplifier circuit 42 or the amplitude amplifier circuit 42A. That is, the waveform shape circuit 4 may have an output node corresponding to the node N4 instead of the output node corresponding to the node N3. It should be noted, however, that the phase of the signal is opposite in the case in which the node N4 is the output node of the amplitude amplifier circuit 42 or the amplitude amplifier circuit 42A, compared to the case in which the node N3 is the output node of the amplitude amplifier circuit 42 or the amplitude amplifier circuit 42A. Ultimately, the oscillation circuit 1 or the semiconductor device 10 may further include a buffer or an inverter, as appropriate, depending on whether the signal has the same phase as or the opposite phase from the phase of the signal to be provided from the output terminal Tout.

For example, the utilization circuit 7 may be any circuit that operates in response to reception of the signal provided by the oscillation circuit 1. The utilization circuit 7 is not limited to the above-mentioned circuit. The utilization circuit 7 may be a mixed circuit of a digital circuit and an analog circuit, such as a data conversion circuit exemplified by an A/D conversion circuit or a D/A conversion circuit. As another example, the utilization circuit 7 may be an analog circuit, such as a clock signal generation circuit, a timing circuit exemplified by a timer or a counter, or a power supply circuit exemplified by a DC/DC converter or a charge pump.

The oscillation circuit 1 and the utilization circuit 7 are illustrated as the configuration of the semiconductor device 10 in FIG. 1, but the semiconductor device 10 may be integrated in combination with circuits having various other functions.

The at least one embodiment and modifications thereof described above are encompassed in the scope and the gist of the invention, and are encompassed in the invention defined in the appended claims and equivalents thereof.

What is claimed is:

1. An oscillation circuit, comprising:
a ring oscillator; and
a waveform shape circuit configured to shape a waveform of an output signal of the ring oscillator,
the waveform shape circuit including:
a preamplifier circuit configured to generate at least a first signal having the same frequency as a frequency of the output signal of the ring oscillator and having an opposite phase from a phase of the output signal of the ring oscillator, and supply the first signal and a second signal having the same frequency as the frequency of the first signal and having an opposite phase from the phase of the first signal; and
an amplitude amplifier circuit including:
a first transistor including a gate for receiving the first signal, a source connected to a first power supply terminal configured to supply a first power supply voltage, and a drain;
a second transistor including a gate for receiving the second signal, a source connected to the first power supply terminal, and a drain;
a third transistor including a drain connected to the drain of the first transistor, a gate connected to the drain of the second transistor, and a source connected to a second power supply terminal configured to supply a second power supply voltage; and
a fourth transistor including a drain connected to the drain of the second transistor, a gate connected to the drain of the first transistor, and a source connected to the second power supply terminal.

2. The oscillation circuit according to claim 1, wherein the preamplifier circuit includes a first inverter including:
a node configured to receive the output signal of the ring oscillator and serve as a supply source of the second signal; and
a node configured to generate the first signal based on the output signal of the ring oscillator and serve as a supply source of the first signal.

3. The oscillation circuit according to claim 1, wherein the preamplifier circuit includes:
a first inverter including a node configured to provide the first signal; and
a second inverter including a node configured to provide the second signal.

4. The oscillation circuit according to claim 1, wherein the preamplifier circuit includes:
an inverter including:
a node configured to provide the first signal;
a first power supply terminal connected to one of the first power supply terminal and the second power supply terminal; and
a second power supply terminal; and
a current control transistor including:
a drain connected to the second power supply terminal; and
a source connected to another one of the first power supply terminal and the second power supply terminal,
the current control transistor being configured to control an electric current for driving the inverter based on an electric current for controlling driving of the ring oscillator.

5. A semiconductor device, comprising:
the oscillation circuit of claim 1; and
a utilization circuit configured to perform predetermined processing in response to reception of a signal provided from the oscillation circuit.

6. A semiconductor device, comprising:
the oscillation circuit of claim 2; and
a utilization circuit configured to perform predetermined processing in response to reception of a signal provided from the oscillation circuit.

7. A semiconductor device, comprising:
the oscillation circuit of claim 3; and
a utilization circuit configured to perform predetermined processing in response to reception of a signal provided from the oscillation circuit.

8. A semiconductor device, comprising:
the oscillation circuit of claim 4; and
a utilization circuit configured to perform predetermined processing in response to reception of a signal provided from the oscillation circuit.
